(19) United States
(12) Patent Application Publication
(10) Pub. No.: US 2024/0096909 A1
(43) Pub. Date: Mar. 21, 2024

(54) CHIP ON FILM PACKAGE AND DISPLAY APPARATUS INCLUDING THE SAME

(71) Applicant: Samsung Electronics Co., Ltd., Suwon-si (KR)

(72) Inventors: Seunghyun Cho, Suwon-si (KR); Jaemin Jung, Suwon-si (KR); Jeongkyu Ha, Suwon-si (KR)

(21) Appl. No.: 18/200,609

(22) Filed: May 23, 2023

(30) Foreign Application Priority Data
Sep. 21, 2022 (KR) 10-2022-0119544

(51) Int. Cl. H01L 27/12; H05K 7/20

(52) U.S. Cl. CPC H01L 27/1244; H05K 7/20954

(57) ABSTRACT

A chip on film (COF) package includes a film substrate including a base film having a mounting region, a main line pattern extending on the base film, and a branch line pattern extending on the base film and electrically connected to the main line pattern, a semiconductor chip vertically overlapping the mounting region, a first bump structure disposed between the semiconductor chip and the film substrate and electrically connected to the main line pattern, and a second bump structure disposed between the semiconductor chip and the film substrate and electrically connected to the branch line pattern, the branch line pattern extends so as not to overlap a first edge of the first bump structure facing a first edge of the mounting region and a first edge of the second bump structure facing the first edge of the mounting region.

### CROSS-REFERENCE TO RELATED APPLICATION

This application is based on and claims priority under 35 U.S.C. § 119 to Korean Patent Application No. 10-2022-0119544, filed on Sep. 21, 2022, in the Korean Intellectual Property Office, the disclosure of which is incorporated by reference herein in its entirety.

### BACKGROUND

The technical spirit of the inventive concept relates to a chip on film (COF) package and a display apparatus including the COF package.

A chip on film (COF) package includes a semiconductor chip such as a display driving chip mounted on a film substrate. In the COF package, the semiconductor chip may be electrically connected to a lead of the film substrate through a bump structure. As display apparatuses have recently been miniaturized, there is a need for a technology of suppressing damage to leads of the film substrate due to external stress while arranging the leads of the film substrate at a fine pitch.

### SUMMARY

The inventive concept provides a chip on film (COF) package with improved reliability.

The inventive concept also provides a display apparatus including the COF package.

According to an aspect of the inventive concept, there is provided a COF package including a film substrate including a base film having a chip mounting region, a main line pattern extending on the base film, and a branch line pattern extending on the base film and electrically connected to the main line pattern, a semiconductor chip mounted on the film substrate so as to overlap the chip mounting region, a first bump structure disposed between the semiconductor chip and the film substrate and electrically connected to the main line pattern, and a second bump structure disposed between the semiconductor chip and the film substrate and electrically connected to the branch line pattern, the second bump structure spaced apart from the first bump structure in a first direction parallel to a first edge of the chip mounting region, the branch line pattern extends so as not to overlap a first edge of the first bump structure facing the first edge of the chip mounting region and a first edge of the second bump structure facing the first edge of the chip mounting region.

According to another aspect of the inventive concept, there is provided a COF package including a film substrate, a semiconductor chip mounted on the film substrate, a plurality of bump structures between the film substrate and the semiconductor chip, the plurality of bump structures including a first bump structure and a second bump structure, an underfill material layer filling a gap between the semiconductor chip and the film substrate, and a heat dissipation resin layer covering the semiconductor chip on the film substrate, the film substrate includes a base film having a chip mounting region and an outer region outside the chip mounting region, the chip mounting region vertically overlapping the semiconductor chip, a main line pattern extending on the chip mounting region of the base film, the main line pattern including a first pad electrically coupled to the first bump structure and a first extension pattern electrically connected to the first pad, a second pad electrically coupled to the second bump structure and spaced apart from the first pad in a first direction parallel to a first boundary of the chip mounting region, and a branch line pattern extending between the main line pattern and the second pad and electrically connecting the first bump structure to the second bump structure, wherein the first pad extends from one edge of the first bump structure to an opposite edge of the first bump structure in a second direction perpendicular to the first direction in a plan view, wherein the second pad extends from one edge of the second bump structure to an opposite edge of the second bump structure in the second direction in the plan view, and wherein the branch line pattern is spaced apart from a first side surface of the first pad most adjacent to the first boundary of the chip mounting region and a first side surface of the second pad most adjacent to the first boundary of the chip mounting region.

According to another aspect of the inventive concept, there is provided a display apparatus including a COF package including a film substrate, a plurality of bump structures on the film substrate, and a display driving chip on the plurality of bump structures, a display panel electrically connected to the film substrate, and a driving printed circuit board electrically connected to the film substrate, the plurality of bump structures include a first bump structure and a second bump structure, the film substrate includes a base film having a chip mounting region and an outer region surrounding the chip mounting region, the chip mounting region vertically overlaps the display driving chip, a main line pattern extending on the chip mounting region of the base film, the main line pattern including a first pad electrically coupled to the first bump structure and a first extension pattern electrically connected to the first pad, a second pad electrically coupled to the second bump structure and spaced apart from the first pad in a first direction parallel to a first boundary of the chip mounting region, and a branch line pattern extending between the main line pattern and the second pad and electrically connecting the first bump structure to the second bump structure, wherein the first pad extends from one edge of the first bump structure to an opposite edge of the first bump structure in a second direction perpendicular to the first direction in a plan view, wherein the second pad extends from one edge of the second bump structure to an opposite edge of the second bump structure in the second direction in the plan view, and wherein the branch line pattern is spaced apart from a first side surface of the first pad most adjacent to the first boundary of the chip mounting region and a first side surface of the second pad most adjacent to the first boundary of the chip mounting region.

### BRIEF DESCRIPTION OF THE DRAWINGS

Embodiments will be more clearly understood from the following detailed description taken in conjunction with the accompanying drawings in which:

FIG. 1 is a cross-sectional view illustrating a chip on film (COF) package according to some embodiments;

FIG. 2 is a plan view illustrating some components of the COF package according to some embodiments;

FIG. 3A is a plan view illustrating a COF package according to some embodiments;

FIG. 3B is a cross-sectional view of the COF package taken along line 3B-3B′ of FIG. 3A;

FIG. 4A is a plan view illustrating a COF package according to a comparative example;

FIG. 4B is a cross-sectional view of the COF package according to a comparative example taken along line 4B-4B′ of FIG. 4A;

FIG. 5 is a plan view illustrating a COF package according to some embodiments;

FIG. 6 is a plan view illustrating a COF package according to some embodiments;

FIG. 7 is a plan view illustrating a COF package according to some embodiments; and

FIG. 8 is a perspective view illustrating a display apparatus according to some embodiments.

### DETAILED DESCRIPTION OF THE EMBODIMENTS

Hereinafter, embodiments of the inventive concept will be described in detail with reference to the accompanying drawings. The same reference numerals are used for the same components in the drawings, and redundant descriptions thereof are omitted.

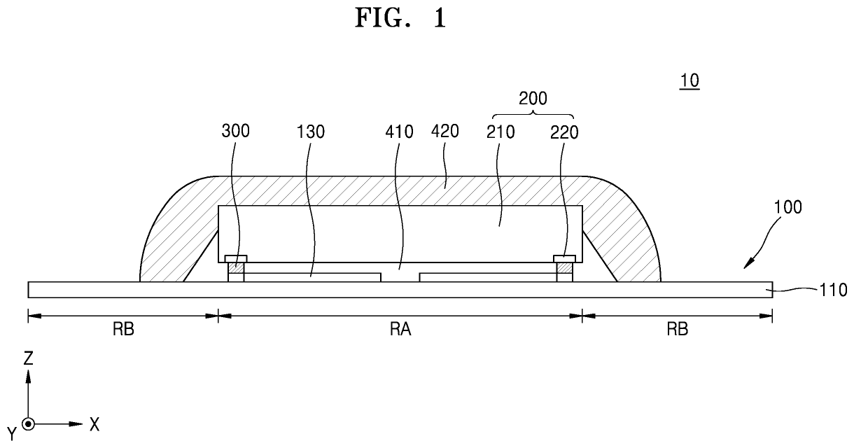

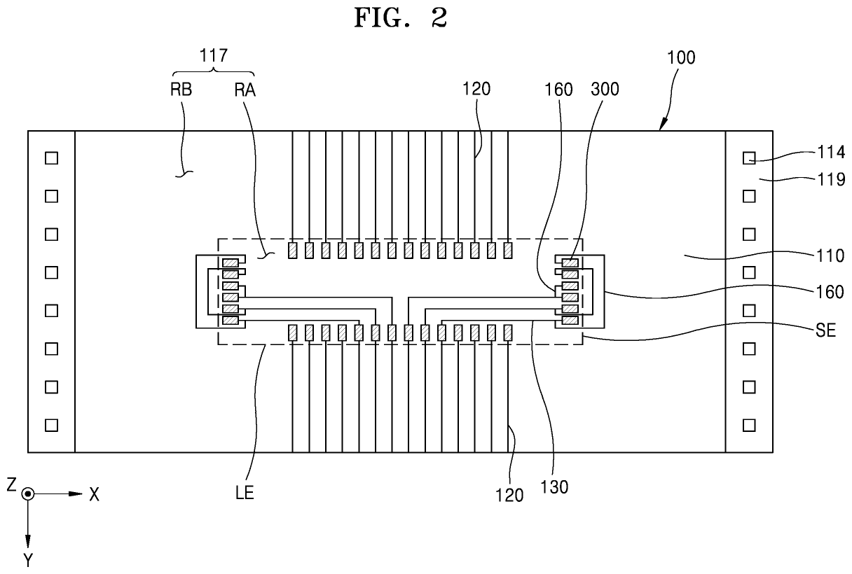

FIG. 1 is a cross-sectional view illustrating a chip on film (COF) package 10 according to some embodiments. FIG. 2 is a plan view illustrating some components of the COF package 10 according to some embodiments.

Referring to FIGS. 1 and 2, the COF package 10 may include a film substrate 100, a semiconductor chip 200, and a plurality of bump structures 300.

The film substrate 100 may include a base film 110 and a conductive interconnect pattern extending on the base film 110.

The base film 110 may be made of an insulating material. The base film 110 may be a flexible film having flexibility. For example, the base film 110 may include or be formed of a resin-based material such as polyimide. For example, the base film 110 may include or be formed of at least one of epoxy resin, acrylic, polyether nitrile, polyether sulfone, polyethylene terephthalate, or polyethylene naphthalate.

The base film 110 may include a circuit region 117 and a perforation (PF) region 119. The circuit region 117 may include a chip mounting region RA where the semiconductor chip 200 is mounted and an outer region RB outside the chip mounting region RA. For example, the outer region RB may surround the chip mounting region RA. In a plan view, the chip mounting region RA may vertically overlap the semiconductor chip 200 and may have the same planar shape as the semiconductor chip 200. For example, the chip mounting region RA may be defined as a region vertically overlapping the semiconductor chip 200 in the circuit region 117. The outer region RB may be the remaining region of the circuit region 117 excluding the chip mounting region RA. The chip mounting region RA and the outer region RB may be regions defined in an upper/top surface of the base film 110 facing the semiconductor chip 200. The PF region 119 may be disposed on both side ends of the base film 110. For example, the PF region 119 may be positioned at opposite ends of the base film 110. The PF region 119 may include a plurality of PF holes 114. Because pitches of the PF holes 114 are constant, the length of the base film 110 may be determined by the number of PF holes 114. The PF region 119 may be cut and removed before the COF package 10 is disposed on a display apparatus.

Hereinafter, a direction parallel to the upper surface of the base film 110 is defined as a horizontal direction (e.g., an X direction and/or a Y direction), and a direction perpendicular to the upper surface of the base film 110 is defined as a vertical direction (e.g., a Z direction).

The conductive interconnect pattern may be disposed on the upper surface of the base film 110 and may extend along the upper surface of the base film 110. The inventive concept is not limited thereto, and the conductive interconnect pattern may be disposed on a lower/bottom surface of the base film 110 and may extend along the lower surface of the base film 110. The conductive interconnect pattern may include or be formed of copper (Cu), aluminum (Al), tin (Sn), gold (Au), nickel (Ni), lead (Pb), palladium (Pd), a solder, or a combination thereof. For example, the conductive interconnect pattern may be formed from aluminum foil or copper foil. For example, the conductive interconnect pattern may be formed through patterning of a metal layer formed on the base film 110 by a casting, laminating, or electroplating method. For example, the line width of the conductive interconnect pattern may be between 5 μm and 15 μm.

The conductive interconnect pattern may include one or more input/output interconnect patterns 120 extending from one or more edges of the base film 110 to the chip mounting region RA and one or more inner interconnect patterns 130 formed/extending inside the chip mounting region RA. The input/output interconnect pattern 120 may be configured to transmit (e.g., may transmit) an input signal provided from the outside and input to the semiconductor chip 200 and/or an output signal output from the semiconductor chip 200 to the outside. For example, the input/output interconnect pattern 120 may electrically connect the semiconductor chip 200 to a component, e.g., a display panel or a printed circuit board, outside the film substrate 100. For example, the input/output interconnect pattern 120 may be configured to transmit (e.g., may transmit) input/output data signals, a control signal, and a power signal (e.g., a Vdd voltage, a Vss voltage, a ground voltage, etc.).

As used herein, components described as being “electrically connected” or “electrically coupled” are configured such that an electrical signal can be transferred from one component to the other (although such electrical signal may be attenuated in strength as it transferred and may be selectively transferred).

The film substrate 100 may further include a protection layer provided on the base film 110. The protection layer may cover a part of the conductive interconnect pattern and the base film 110. The protection layer may cover the conductive interconnect pattern, but may not cover parts of the conductive interconnect pattern, e.g., bump pads, contacting the plurality of bump structures 300. For example, the conductive interconnect pattern may include the bump pads. The conductive interconnect pattern and a heat dissipation resin layer 420 may not contact and may be blocked by the protection layer interposed therebetween. In some embodiments, the protection layer may include or may be solder resist or dry film resist.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The semiconductor chip 200 may be mounted on the film substrate 100. The semiconductor chip 200 may be disposed on the chip mounting region RA of the base film 110. The semiconductor chip 200 may include or may be a display driver IC (DDI) used to drive the display apparatus. In this case, the COF package 10 may correspond to a DDI package including the DDI. The type of semiconductor chip 200 is not limited thereto, and the semiconductor chip 200 may include or may be a memory chip and/or a logic chip. In addition, FIGS. 1 and 2 show that the COF package 10 includes one semiconductor chip 200, but the number of semiconductor chips 200 is not limited thereto. For example, the COF package 10 may include a plurality of semiconductor chips 200 spaced apart in the horizontal direction (e.g., the X direction and/or the Y direction) on the film substrate 100.

The semiconductor chip 200 may have a rectangular shape in a plan view. For example, in a plan view, the semiconductor chip 200 may have a short side extending in a first horizontal direction (e.g., the Y direction) and a long side extending in a second horizontal direction (e.g., the X direction) perpendicular to the first horizontal direction (e.g., the Y direction). In some embodiments, the length of the long side of the semiconductor chip 200 may be equal to or greater than about 1.5 times the length of the short side.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

In a plan view, the chip mounting region RA of the film substrate 100 may have the same shape and the same dimensions as the semiconductor chip 200. For example, the chip mounting region RA may completely overlap the semiconductor chip 200 to have a rectangular shape, and the length of the chip mounting region RA in the first horizontal direction (e.g., the Y direction) and the length thereof in the second horizontal direction (e.g., the X direction) may be respectively the same as the length of the semiconductor chip 200 in the first horizontal direction (e.g., the Y direction) and the length thereof in the second horizontal direction (e.g., the X direction). The chip mounting region RA may have a pair of first edges SE extending in the first horizontal direction (e.g., the Y direction) and a pair of second edges LE extending in the second horizontal direction (e.g., the X direction), wherein the first edges SE of the chip mounting region RA may be the short sides of the chip mounting region RA, and the second edges LE of the chip mounting region RA may be the long sides of the chip mounting region RA. The length of the second edges LE of the chip mounting region RA may be equal to or greater than about 1.5 times the length of the first edges SE of the chip mounting region RA.

The semiconductor chip 200 may include a substrate 210 and a plurality of chip pads 220.

The substrate 210 is a semiconductor substrate and may include a lower/bottom surface and an upper/top surface that are opposite to each other. The lower surface of the substrate 210 is a surface facing the film substrate 100 and may be an active surface of the substrate 210. The upper surface of the substrate 210 may be a non-active surface of the substrate 210. The substrate 210 may be a silicon (Si) wafer including or formed of crystalline silicon, polycrystalline silicon, or amorphous silicon. Alternatively, the substrate 210 may include a semiconductor element such as germanium (Ge) or a compound semiconductor such as silicon carbide (SiC), gallium arsenide (GaAs), indium arsenide (InAs), and indium phosphide (InP). The plurality of chip pads 220 of the semiconductor chip 200 may be disposed on the lower surface of the semiconductor chip 200 and may be made of a conductive material.

The plurality of bump structures 300 may be disposed between the semiconductor chip 200 and the film substrate 100. Each of the plurality of bump structures 300 may have a pillar shape extending in the vertical direction (e.g., the Z direction) between the semiconductor chip 200 and the film substrate 100. The plurality of bump structures 300 may physically and electrically connect the semiconductor chip 200 to the film substrate 100. For example, the plurality of bump structures 300 may contact the bottom surface of the semiconductor chip 200 and a top surface of the film substrate 100. The semiconductor chip 200 may be mounted on the film substrate 100 in a flip chip method through the plurality of bump structures 300. Each of the plurality of bump structures 300 may be coupled to (e.g., contact) the corresponding chip pad 220 of the semiconductor chip 200 and a corresponding pad part, e.g., a corresponding bump pad, of the conductive interconnect pattern.

For example, the bump structure 300 may be made of chromium (Cr), tungsten (W), titanium (Ti), copper (Cu), nickel (Ni), aluminum (Al), palladium (Pd), gold (Au), or a combination thereof. For example, the bump structure 300 may be formed through an electroplating process. In some embodiments, a material of the bump structure 300 may be different from a material of the conductive interconnect pattern. In some embodiments, the bump structure 300 may be made of gold (Au), and the conductive interconnect pattern may be made of copper.

The plurality of bump structures 300 may include the bump structures 300 disposed/positioned adjacent to the first edge/boundary SE of the chip mounting region RA or the short side of the semiconductor chip 200 and arranged along the first boundary/edge SE of the chip mounting region RA or the short side of the semiconductor chip 200 and the bump structures 300 adjacent to the second edge/boundary LE of the chip mounting region RA or the long side of the semiconductor chip 200 and arranged along the second boundary/edge LE of the chip mounting region RA or the long side of the semiconductor chip 200. The bump structures 300 arranged along the long side of the semiconductor chip 200 may be connected to the input/output interconnect patterns 120. For example, the bump structures 300 arranged along the long side of the semiconductor chip 200 may be electrically/directly connected to (e.g., contact) the input/output interconnect patterns 120. In some embodiments, the bump structure 300 near the first edge/boundary SE of the chip mounting region RA and the bump structure 300 near the second edge/boundary LE of the chip mounting region RA may be electrically connected to each other through the inner interconnect pattern 130.

For example, each of the plurality of bump structures 300 may have a rectangular shape in a plan view, and may have a long side and a short side. In each of the plurality of bump structures 300, the length of the short side may be between 10 μm and 20 μm, the length of the long side may be between 30 μm and 50 μm, and the height (i.e., a length in the vertical direction (e.g., the Z direction)) may be between 10 μm and 20 μm. In addition, a first pitch interval (e.g., a distance between centers of adjacent, e.g., directly adjacent or closest two, bump structures 300) of the bump structures 300 may be between 40 μm and 80 μm.

In each of the plurality of bump structures 300, a direction (i.e., a long axis) in which the long side extends may be perpendicular to an edge/boundary of an adjacent chip mounting region RA. For example, in the bump structures 300 arranged along the first boundary/edge SE of the chip mounting region RA, a direction in which the long sides of the bump structures 300 extend may be perpendicular to the first boundary/edge SE of the chip mounting region RA. For example, in the bump structures 300 arranged along the second edge/boundary LE of the chip mounting region RA, a direction in which the long sides of the bump structures 300 extend may be perpendicular to the second boundary/edge LE of the chip mounting region RA.

In some embodiments of the inventive concept, the conductive interconnect pattern of the film substrate 100 may include a branch line pattern 160 extending between the bump structures 300 arranged along the first edge/boundary SE of the chip mounting region RA as shown in FIG. 2. The branch line pattern 160 may be connected (e.g., electrically and directly) to the inner interconnect pattern 130, and the bump structures 300 connected to each other through the branch line pattern 160 may be configured to receive (e.g., may receive) a common signal through the inner interconnect pattern 130 and the branch line pattern 160. For example, the bump structures 300 connected to each other through the branch line pattern 160 may be configured to receive (e.g., may receive) the same power signal (e.g., one of the Vdd voltage, the Vss voltage, and the ground voltage).

The chip on film package 10 may include an underfill material layer (or an underfill) 410 that fills a gap between the semiconductor chip 200 and the film substrate 100 and at least partially covers (e.g., contact) a sidewall of the semiconductor chip 200. The underfill material layer 410 may cover/contact sidewalls of the bump structures 300 between the semiconductor chip 200 and the film substrate 100 and cover/contact the conductive interconnect pattern. The underfill material layer 410 may be made of an insulating material. The underfill material layer 410 may be formed of, for example, epoxy resin. For example, the underfill material layer 410 may be formed by a capillary underfill process.

The COF package 10 may include a heat dissipation resin layer 420 covering the semiconductor chip 200. For example, the heat dissipation resin layer 420 may contact a top surface and a side surface of the semiconductor chip 200. The heat dissipation resin layer 420 may seal the semiconductor chip 200 and may cover/contact a surface of the underfill material layer 410 and a part of the film substrate 100 around the semiconductor chip 200. For example, the heat dissipation resin layer 420 may encapsulate the semiconductor chip 200 in combination with the underfill material layer 410 and the film substrate 100. The heat dissipation resin layer 420 may be made of a resin (a resin material) containing a filler. In some embodiments, the filler included in the heat dissipation resin layer 420 may include or may be a thermal conductive filler (e.g., a metal filler) made of a material with high thermal conductivity.

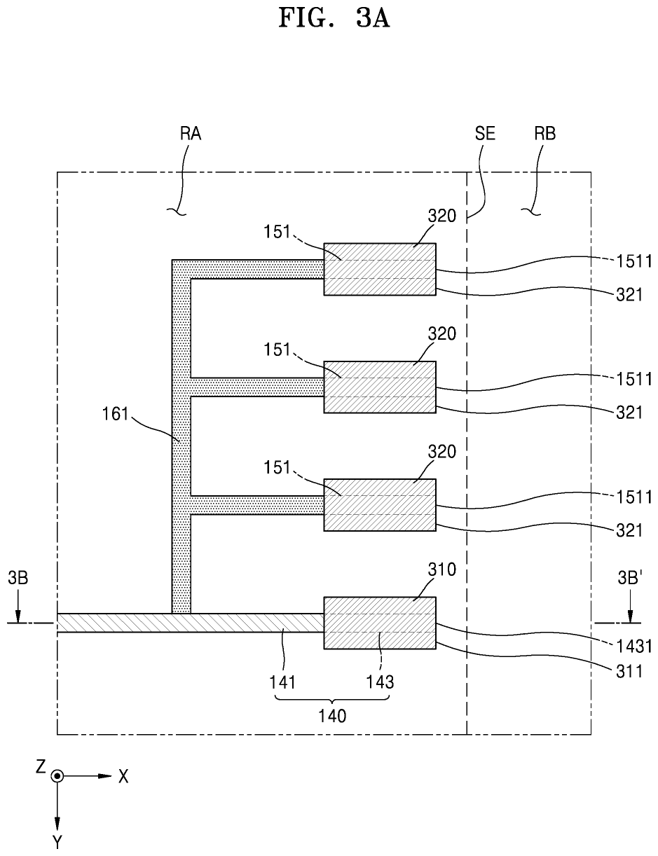

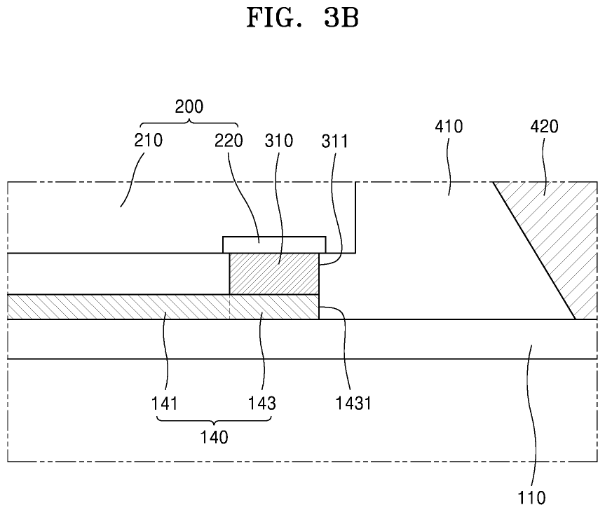

FIGS. 3A and 3B are diagrams illustrating a COF package according to some embodiments. FIG. 3A is a plan view illustrating the COF package. FIG. 3B is a cross-sectional view of the COF package taken along line 3B-3B′ of FIG. 3A.

Referring to FIGS. 1, 3A, and 3B, bump structures (e.g., a first bump structure 310 and second bump structures 320) may be arranged along the first edge/boundary SE of the chip mounting region RA, and the film substrate 100 may include bump pads disposed on the lower side of the bump structures and coupled to the bump structures. For example, the bump pads may be respectively placed below the bump structures and may be electrically and directly connected to (e.g., contact) the bump structures. Each bump pad may have a substantially rectangular parallelepiped shape. Each bump pad may have a rectangular shape having a long side and a short side in a plan view. Each bump pad may extend in a long axis/side direction (i.e., the second horizontal direction (e.g., the X direction)) of the corresponding bump structure, and may linearly extend from one edge to the other edge of the bump structure, e.g., in a plan view. For example, a plurality of bump pads may be arranged on the base film 110 along the first boundary/edge SE of the chip mounting region RA extending in parallel to the first horizontal direction (e.g., the Y direction). In a plan view, each of the plurality of bump pads may have a rectangular shape of which length in the second horizontal direction (e.g., the X direction) is greater than the length in the first horizontal direction (e.g., the Y direction).

In some embodiments, a conductive cover layer may be disposed on outer surfaces of the bump pads to increase adhesion between the bump pads and the bump structures. In certain embodiments, the bump pads may include a conductive cover layer formed in an upper portion of the bump pads. The conductive cover layer may include or be formed of, for example, at least one of tin (Sn), nickel (Ni), lead (Pb), palladium (Pd), or a solder.

The film substrate 100 may include a main line pattern 140 and a branch line pattern 161 that extend on the base film 110 and are connected (e.g., electrically and/or directly) to each other. For example, the main line patter 140 and the branch line pattern 161 may be integrally formed as one body. The main line pattern 140 may be connected (e.g., electrically and/or directly) to (e.g., contact) the first bump structure 310 that is one of the bump structures, and the branch line pattern 161 may extend from a point of the main line pattern 140 to the second bump structure 320 that is one of the bump structures. In some embodiments, the branch line pattern 161 may contact a first extension pattern 141 of the main line pattern 140. The main line pattern 140 may extend only within the chip mounting region RA of the base film 110. The branch line patterns 161 may be disposed within the chip mounting region RA and/or the outer region RB of the base film 110. The entire branch line pattern 161 may be within the chip mounting region RA of the base film 110 or may extend over both the chip mounting region RA and the outer region RB.

For example, a bump pad arranged on the second edge LE may be electrically connected to two or more bump pads arranged on the first edge SE through a conductive interconnect pattern, and the conductive interconnect pattern portion having the shortest path (or a shorter path than the other in case two bump pads on the first edge SE are connected to the conductive interconnect pattern) may be the main line pattern 140, and the other portions may be the branch line pattern(s) 161 when the main line pattern 140 and the branch line pattern 161 are integrally formed as one body and the entire branch line pattern 161 is within the chip mounting region RA. In this case, when the conductive interconnect pattern has the same two shortest path length between the bump pad on the second edge LE and two bump pads on the first edge SE electrically connected to each other, either one portion may be the main line pattern 140 and the other portion may be a branch line pattern. When a portion of the conductive interconnect pattern electrically connected to and extending from a bump pad on the first edge SE is formed of different material/layer from the conductive interconnect pattern extending from the bump pad on the second edge LE electrically connected to the bump pad on the first edge SE, the different portion of the conductive interconnect pattern is a branch line pattern.

The main line pattern 140 may include a first pad 143 coupled to (e.g., electrically connected to and/or contacting) the first bump structure 310 and a first extension pattern 141 extending from one side of the first pad 143 along the surface of the base film 110. One end portion (e.g., one end) of the branch line pattern 161 may be electrically connected to and/or contact the first extension pattern 141 of the main line pattern 140, and the other end portion (e.g., the other end) of the branch line pattern 161 may be electrically connected to and/or may contact one side of the second pad 151 electrically coupled to and/or contacting the second bump structure 320. Each of the first pad 143 and the second pad 151 may be one of the bump pads described above. For example, the bump pads may include the first pad 143 and the second pad 151. The first pad 143 may linearly extend from a first edge 311 of the first bump structure 310 to the other edge (e.g., an opposite edge to the first edge 311) of the first bump structurer 310, e.g., in a plan view, in the second horizontal direction (e.g., the X direction), and the second pad 151 may linearly extend from a first edge 321 of the second bump structure 320 to the other edge (e.g., an opposite edge to the first edge 321) of the second bump structure, e.g., in a plan view, in the second horizontal direction (e.g., the X direction).

For example, the first pad 143 may have the same width in the first direction (Y direction) and the same height in the third direction (Z direction) as the ones of the first extension pattern 141, and the second pad 151 may have the same width in the first direction (Y direction) and the same height in the third direction (Z direction) as the ones of the branch line pattern 161. When a conductive interconnect pattern extending from a bump pad has the same width as the width of the bump pad in a horizontal direction perpendicular to a lengthwise direction of the conductive interconnect pattern and/or the bump pad, the bump pad may be the entire portion of the conductive interconnect pattern vertically overlapping a bump structure disposed on the bump pad. In certain embodiments, a bump pad may have a different width (e.g., a greater width) from a conductive interconnect pattern extending from the bump pad, and a portion or the whole portion of the bump pad may vertically overlap a bump structure. In this case, the bump pad may be the whole portion of which the width is different from the width of the conductive interconnect pattern extending from the bump pad. Here, the widths are distances of the patterns in a direction perpendicular to the lengthwise direction of the bump pad and/or the conductive interconnect pattern.

When the first edge 311 of the first bump structure 310 is defined as an edge facing the first edge/boundary SE of the chip mounting region RA or most adjacent to the first boundary/edge SE of the chip mounting region RA, and the first edge 321 of the second bump structure 320 is defined as an edge facing the first boundary/edge SE of the chip mounting region RA or most adjacent to the first edge/boundary SE of the chip mounting region RA, the branch line pattern 161 does not overlap the first edge 311 of the first bump structure 310 and the first edge 321 of the second bump structure 320. For example, when a first side surface 1431 of the first pad 143 is defined as a side surface facing the first edge/boundary SE of the chip mounting region RA or most adjacent to the first edge/boundary SE of the chip mounting region RA, and a first side surface 1511 of the second pad 151 is defined as a side surface facing the first edge/boundary SE of the chip mounting region RA or most adjacent to the first boundary/edge SE of the chip mounting region RA, the branch line pattern 161 is not connected to the first side surface 1431 of the first pad 143 and the first side surface 1511 of the second pad 151. For example, the branch line pattern 161 may be directly connected to or may contact and/or extend from a side surface of the second pad 151 other than the first side surface 1511 of the second pad 151.

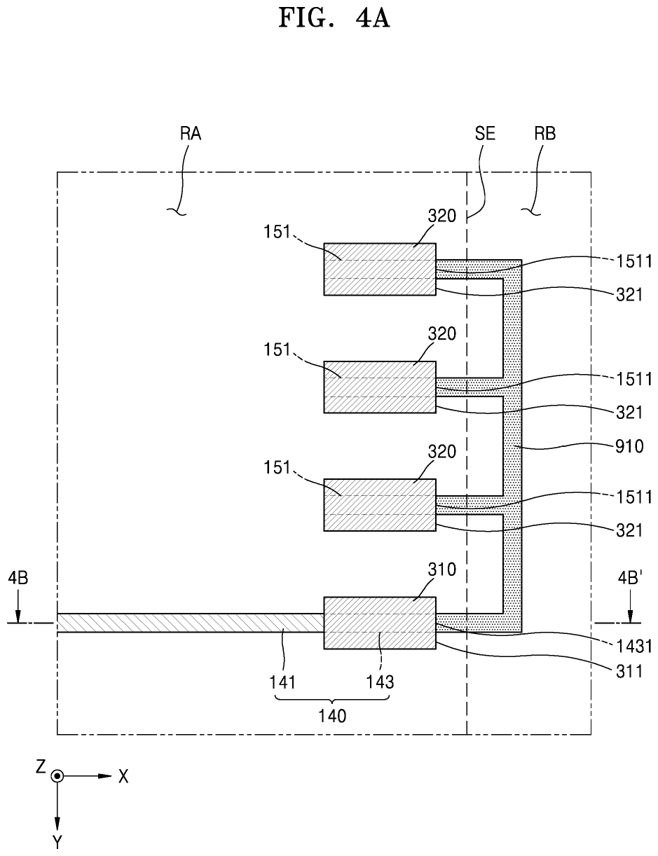

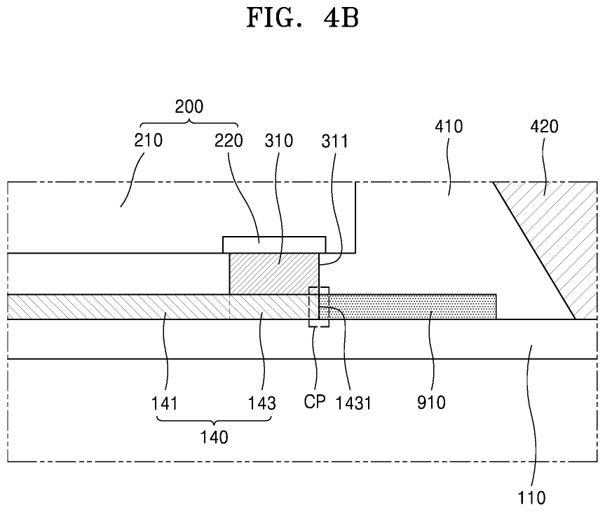

FIGS. 4A and 4B are diagrams illustrating a COF package according to a comparative example. FIG. 4A is a plan view illustrating the COF package according to the comparative example. FIG. 4B is a cross-sectional view of the COF package according to the comparative example taken along line 4B-4B′ of FIG. 4A.

Referring to FIGS. 4A and 4B, the COF package according to the comparative example includes a conductive pattern 910 extending on the base film 110 to connect the first bump structure 310 to the second bump structure 320. The conductive pattern 910 extends between the first side surface 1431 of the first pad 143 and the first side surface 1511 of the second pad 151. When thermal deformation occurs in the COF package according to the comparative example, deformation such as bending occurs in the film substrate 100, and stress concentrates on a connection part between the conductive pattern 910 and the first pad 143 and a connection part between the conductive pattern 910 and the second pad 151. For example, when the COF package includes the heat dissipation resin layer 420, thermal deformation tends to be more severe. Such concentration of stress causes cracks in the connection part CP between the conductive pattern 910 and the first pad 143 and the connection part between the conductive pattern 910 and the second pad 151, and these cracks result in short-circuit of wiring, which causes electrical defects in the COF package.

However, in the COF package according to some embodiments, the branch line pattern 161 electrically connecting the bump structures to each other is designed to extend to bypass a part on which stress is likely to concentrate during thermal deformation of the COF package. For example, one end portion (e.g., one end) of the branch line pattern 161 is in contact with the first extension pattern 141 of the main line pattern 140, and the other end portion (e.g., the other end) of the branch line pattern 161 is in contact with a third side surface of the second pad 151 opposite to the first side surface 1511 of the second pad 151. The branch line pattern 161 may be spaced apart from the first side surface 1431 of the first pad 143 most adjacent to the first edge SE of the chip mounting region RA and the first side surface 1511 of the second pad 151 most adjacent to the first edge SE of the chip mounting region RA, and may extend by bypassing a region between the first edge SE of the chip mounting region RA and the first side surface 1431 of the first pad 143 and a region between the first edge SE of the chip mounting region RA and the first side surface 1511 of the second pad 151. For example, the branch line pattern 161 may electrically connect the first pad 143 and the second pad 151 by contacting side surfaces of the respective first pad 143 and the second pad 151 other than side surfaces facing the first edge SE of the chip mounting region RA. In a plan view, the branch line pattern 161 extends along a path that does not overlap the first edge 311 of the first bump structure 310 and the first edge 321 of the second bump structure 320 and electrically connects the first bump structure 310 to the second bump structure 320. A wiring (e.g., the branch line pattern 161) is not disposed in a region on which stress is likely to concentrate during thermal deformation of the COF package, e.g., between the first edge SE of the chip mounting region RA and bump pads 143 and 151, and thus, an electrical defect issue due to thermal deformation of the COF package may be removed. Therefore, according to the COF package according to some embodiments, the conductive wiring pattern of the film substrate 100 may prevent a voltage drop by directly transmitting a power signal to the bump structures near the short side of the semiconductor chip 200, and improve reliability of the COF package by removing the electrical defect issue due to thermal deformation of the COF package.

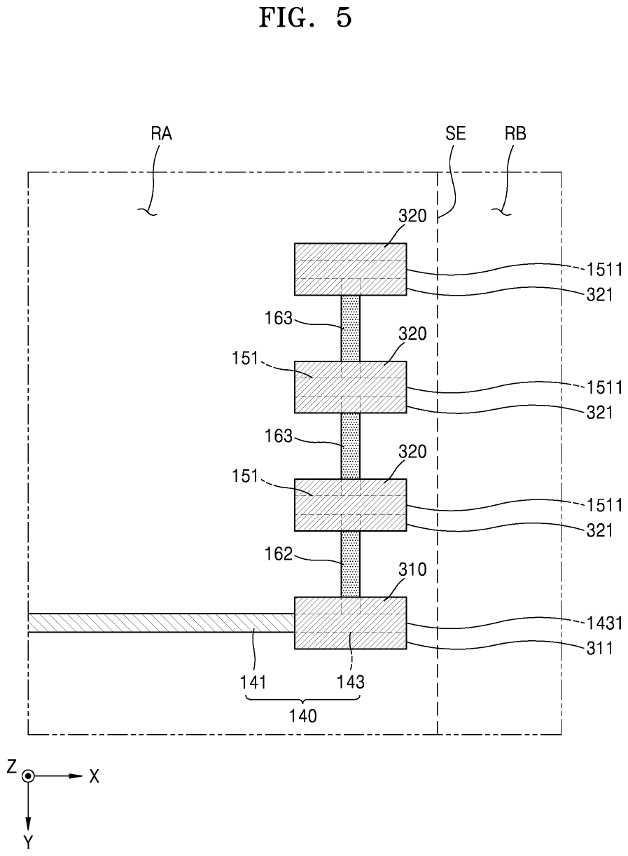

FIGS. 5 to 7 are plan views illustrating COF packages according to some embodiments.

Referring to FIG. 5 together with FIG. 1, the film substrate 100 may include branch line patterns (e.g., a first branch line patterns 162 and a second branch line patterns 163) electrically connecting bump structures to each other (e.g., the first bump structure 310 and the second bump structure 320) arranged along the first edge/boundary SE of the chip mounting region RA.

The first branch line pattern 162 may extend between the first pad 143 of the main line pattern 140 and the second pad 151. For example, one end portion (e.g., one end) of the first branch line pattern 162 may be connected (e.g., electrically/directly) to the first pad 143 and the other end portion (e.g., the other end) of the first branch line pattern 162 may be connected (e.g., electrically/directly) to the second pad 151. When a second side surface of the first pad 143 is defined as a side surface connected to the first side surface 1431 of the first pad 143, and a second side surface of the second pad 151 is defined as a side surface connected to the first side surface 1511 of the second pad 151, the first branch line pattern 162 may extend between the second side surface of the first pad 143 and the second side surface of the second pad 151, which face each other in the first horizontal direction (e.g., the Y direction). The first branch line pattern 162 extends by bypassing a part (i.e., a region overlapping the first edge 311 of the first bump structure 310 and the first edge 321 of the second bump structure 320) on which stress is likely to concentrate during thermal deformation of the COF package, thereby removing an electrical defect issue due to thermal deformation of the COF package. For example, the first branch line pattern 162 is formed within the chip mounting region RA and avoids extending to a region between the first boundary SE and the pads 143 and 151.

Also, the second branch line pattern 163 may extend between neighboring second pads 151 in the first horizontal direction (e.g., the Y direction). For example, one end portion (e.g., one end) of the second branch line pattern 163 may be electrically connected to (e.g., contact) the second pad 151 and the other end portion (e.g., the other end) of the second branch line pattern 163 may be electrically connected to (e.g., may contact) the other second pad 151. The second branch line pattern 163 may extend between a second side surface of the second pad 151 and another second side surface of the second pad 151 facing each other in the first horizontal direction (e.g., the Y direction). The second branch line pattern 163 extends by bypassing a part (i.e., a region overlapping the first edge 321 of the second bump structure 320) on which stress is likely to concentrate during thermal deformation of the COF package, thereby removing an electrical defect issue due to thermal deformation of the COF package.

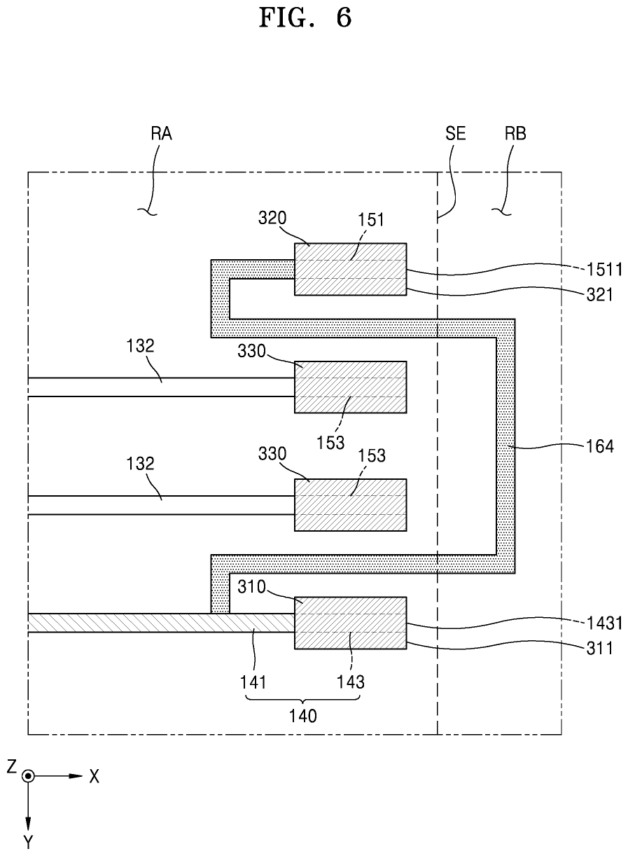

Referring to FIG. 6 together with FIG. 1, the film substrate 100 may include a branch line pattern 164 electrically connecting the first bump structure 310 to the second bump structure 320 spaced apart from each other along the first edge/boundary SE of the chip mounting region RA. The first bump structure 310 and the second bump structure 320 may be spaced apart in the first horizontal direction (e.g., the Y direction) with one or more third bump structures 330 disposed therebetween. The third bump structure 330 may be disposed on the third pad 153, and the third pad 153 may be connected (e.g., electrically/directly) to the interconnect pattern 132 extending on the base film 110.

The branch line pattern 164 may extend from the main line pattern 140 to the second pad 151 to which the second bump structure 320 is electrically coupled, and may pass through the outer region RB of the base film 110. The branch line pattern 164 may extend along a path extending through the outer region RB of the base film 110 so as not to interfere with the interconnect pattern 132. A part of the branch line pattern 164 is covered by the semiconductor chip 200, and another part of the branch line pattern 164 is not covered by the semiconductor chip 200. For example, in a plan view, a part of the branch line pattern 164 in the chip mounting region RA is covered by the semiconductor chip 200, and another part of the branch line pattern 164 in the outer region RB is not covered by the semiconductor chip 200. For example, the branch line pattern 164 may electrically connect the first pad 143 and the second pad 151 by extending on the chip mounting region RA and the outer region RB and by avoiding extending a region between the first boundary SE and bump pads, e.g., the third pads 153.

One end portion (e.g., one end) of the branch line pattern 164 is in contact with the first extension pattern 141 of the main line pattern 140, and the other end portion (e.g., the other end) of the branch line pattern 164 is in contact with a third side surface of the second pad 151 opposite to the first side surface 1511 of the second pad 151. The branch line pattern 164 extends along a path bypassing the first edge 311 of the first bump structure 310 and the first edge 321 of the second bump structure 320 and electrically connect the first bump structure 310 to the second bump structure 320. The branch line pattern 164 extends by bypassing a part (i.e., a region overlapping the first edge 311 of the first bump structure 310 and the first edge 321 of the second bump structure 320) on which stress is likely to concentrate during thermal deformation of the COF package, thereby removing an electrical defect issue due to thermal deformation of the COF package.

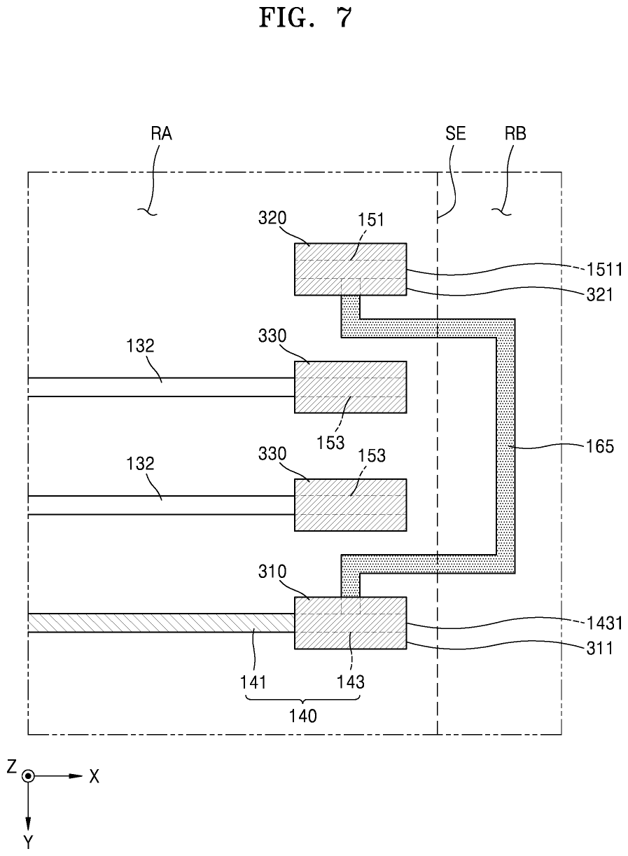

Referring to FIG. 7 together with FIG. 1, the film substrate 100 may include a branch line pattern 165 electrically connecting the first bump structure 310 to the second bump structure 320 spaced apart from each other in the first horizontal direction (e.g., the Y direction) with a third bump structure disposed therebetween. The branch line pattern 165 extends from the main line pattern 140 to the second pad 151 to which the second bump structure 320 is electrically coupled, and may pass through the outer region RB of the base film 110. One end portion (e.g., one end) of the branch line pattern 165 may be connected (e.g., electrically/directly) to (e.g., may contact) the second side surface of the first pad 143 and the other end portion (e.g., the other end) of the branch line pattern 165 may be electrically connected to (e.g., may contact) the second side surface of the second pad 151. The branch line pattern 165 extends along a path bypassing the first edge 311 of the first bump structure 310 and the first edge 321 of the second bump structure 320 and electrically connect the first bump structure 310 to the second bump structure 320. The branch line pattern 165 extends by bypassing a part (i.e., a region overlapping the first edge 311 of the first bump structure 310 and the first edge 321 of the second bump structure 320) on which stress is likely to concentrate during thermal deformation of the COF package, thereby removing an electrical defect issue due to thermal deformation of the COF package.

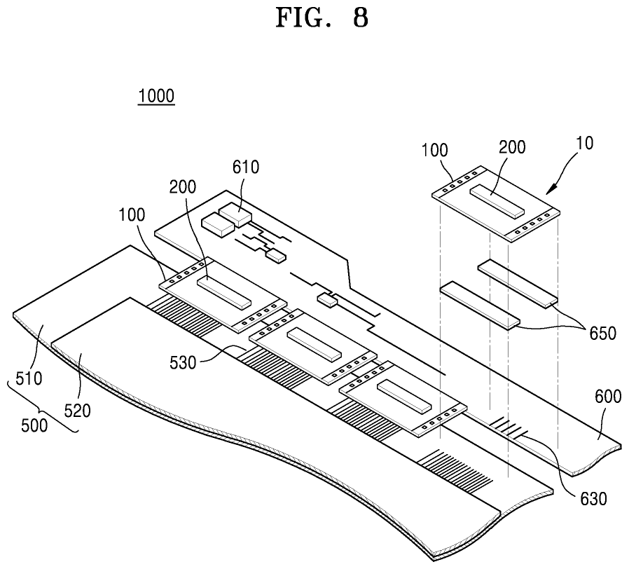

FIG. 8 is a perspective view illustrating a display apparatus 1000 according to some embodiments.

Referring to FIG. 8, the display apparatus 1000 may include at least one COF package 10, a driving printed circuit board 600, and a display panel 500.

The COF package 10 may correspond to any one of the COF packages described above with reference to FIGS. 1 to 3B and 5 to 7. For example, each of the COF packages 10 illustrated in FIG. 8 may be any one of the COF packages disclosed above.

The COF package 10 may include the film substrate 100 and the semiconductor chip 200 mounted on the film substrate 100. In some embodiments, the single COF package 10 may include the single semiconductor chip 200. In some embodiments, the single COF package 10 may include a plurality of semiconductor chips 200 of different types. In certain embodiments, each COF package may include a plurality of identical semiconductor chips or different semiconductor chips. For example, the COF package 10 may include the semiconductor chip 200 electrically connected to the gate lines of the display panel 500 and configured to perform a function of a gate driver and/or and the semiconductor chip 200 electrically connected to source lines of the display panel 500 and configured to perform a function of a source driver. For example, the semiconductor chip 200 included in each COF package 10 may be a gate driver or a source driver.

The COF package 10 is positioned between the driving printed circuit board 600 and the display panel 500, and may be electrically connected to each of the driving printed circuit board 600 and the display panel 500. The COF package 10 may receive a signal output from the driving printed circuit board 600 and transmit the signal to the display panel 500.

One or more driving circuit chips 610 capable of simultaneously or sequentially applying power and signals to the COF package 10 may be mounted on the driving printed circuit board 600.

The display panel 500 may be, for example, a liquid crystal display (LCD) panel, a light emitting diode (LED) panel, an organic LED (OLED) panel, or a plasma display panel (PDP).

The COF package 10 may be electrically connected to each of a driving connection wiring 630 of the driving printed circuit board 600 and a panel connection wiring 530 of the display panel 500.

In some embodiments, the single COF package 10 may be connected to and placed between the driving printed circuit board 600 and the display panel 500. For example, when the display panel 500 is for providing a screen of a small region, such as a mobile phone, or supports a relatively low resolution, the display apparatus 1000 may include the single COF package 10. In some embodiments, a plurality of COF packages 10 may be connected to and placed between the driving printed circuit board 600 and the display panel 500. For example, when the display panel 500 is for providing a screen of a large region, such as a television or supports a relatively high resolution, the display apparatus 1000 may include the plurality of COF packages 10.

The COF package 10 may be connected to at least one side of the display panel 500. For example, one or more COF packages 10 may be connected to only one of four sides of the display panel 500, and the COF package 10 may not be connected to the other three sides of the display panel 500. Alternatively, one or more COF packages 10 may be connected to two or more sides of the display panel 500, respectively. For example, the one or more COF packages 10 may be connected to each of two sides of the display panel 500 connected to each other.

The display panel 500 may include a transparent substrate 510, an image region 520 formed on the transparent substrate 510, and a panel connection wiring 530. The transparent substrate 510 may be, for example, a glass substrate or a flexible substrate. A plurality of pixels of the image region 520 may be electrically connected to a plurality of corresponding panel connection wirings 530 and operate according to signals provided by the semiconductor chip 200 mounted on the COF package 10.

An input pad may be formed on one end of the COF package 10 and an output pad may be formed on the other end thereof. The input pad and the output pad may be respectively connected to the driving connection wiring 630 of the driving printed circuit board 600 and the panel connection wiring 530 of the display panel 500 by an anisotropic conductive layer 650. The anisotropic conductive layer 650 may be, for example, an anisotropic conductive film or an anisotropic conductive paste. The anisotropic conductive layer 650 may have a structure in which conductive particles are dispersed in an insulating adhesive layer. The anisotropic conductive layer 650 may have anisotropic electrical characteristics of an electrical conduction only in the vertical direction and insulation in the horizontal direction.

While the inventive concept has been particularly shown and described with reference to embodiments thereof, it will be understood that various changes in form and details may be made therein without departing from the spirit and scope of the following claims.

What is claimed is:

1. A chip on film (COF) package comprising:
a film substrate comprising a base film having a chip mounting region, a main line pattern extending on the base film, and a branch line pattern extending on the base film and electrically connected to the main line pattern;
a semiconductor chip mounted on the film substrate so as to overlap the chip mounting region;
a first bump structure disposed between the semiconductor chip and the film substrate and electrically connected to the main line pattern; and
a second bump structure disposed between the semiconductor chip and the film substrate and electrically connected to the branch line pattern, the second bump structure spaced apart from the first bump structure in a first direction parallel to a first edge of the chip mounting region,
wherein the branch line pattern extends so as not to overlap a first edge of the first bump structure facing the first edge of the chip mounting region and a first edge of the second bump structure facing the first edge of the chip mounting region.

2. The COF package of claim 1, wherein
the chip mounting region has a rectangular shape in a plan view, and
a length of the first edge of the chip mounting region is smaller than a length of a second edge of the chip mounting region extending in a second direction perpendicular to the first direction.

3. The COF package of claim 1, wherein the main line pattern and the branch line pattern are configured to transmit the same power signal.

4. The COF package of claim 1, wherein
the main line pattern includes a first pad electrically coupled to the first bump structure and a first extension pattern extending from one side of the first pad,
the film substrate further includes a second pad electrically coupled to the second bump structure,
the first pad extends from one edge of the first bump structure to an opposite edge of the first bump structure in a second direction perpendicular to the first direction in a plan view, and
the second pad extends from one edge of the second bump structure to an opposite edge of the second bump structure in the second direction in the plan view.

5. The COF package of claim 4, wherein one end of the branch line pattern contacts the first extension pattern and the other end of the branch line pattern contacts one side surface of the second pad.

6. The COF package of claim 4, wherein the branch line pattern extends from one side surface of the first pad to one side surface of the second pad, wherein the one side surface of the first pad and the one side surface of the second pad face each other in the first direction.

7. The COF package of claim 4, wherein the branch line pattern passes through an outer region of the base film outside the chip mounting region and extends from the main line pattern to the second pad.

8. The COF package of claim 7, wherein
the film substrate further includes a third pad between the first pad and the second pad in the first direction,
the COF package further comprising a third bump structure disposed between the third pad and the semiconductor chip.

9. The COF package of claim 1, further comprising a heat dissipation resin layer covering the semiconductor chip on the film substrate.

10. The COF package of claim 1, further comprising an underfill resin layer between the film substrate and the semiconductor chip, the underfill resin layer surrounding a sidewall of the first bump structure and a sidewall of the second bump structure.

11. The COF package of claim 1, wherein
each of the main line pattern and the branch line pattern includes copper, and
each of the first bump structure and the second bump structure includes gold.

12. The COF package of claim 1, wherein
each of the first bump structure and the second bump structure has a length between about 10 μm and about 20 μm in the first direction, and
each of the first bump structure and the second bump structure has a length between about 30 μm and about 50 μm in a second direction perpendicular to the first direction.

13. A chip on film (COF) package comprising:
a film substrate;
a semiconductor chip mounted on the film substrate;
a plurality of bump structures between the film substrate and the semiconductor chip, the plurality of bump structures comprising a first bump structure and a second bump structure;
an underfill material layer filling a gap between the semiconductor chip and the film substrate; and
a heat dissipation resin layer covering the semiconductor chip on the film substrate,
wherein the film substrate comprises:
a base film having a chip mounting region and an outer region outside the chip mounting region, the chip mounting region vertically overlapping the semiconductor chip;
a main line pattern extending on the chip mounting region of the base film, the main line pattern comprising a first pad electrically coupled to the first bump structure and a first extension pattern electrically connected to the first pad;
a second pad electrically coupled to the second bump structure and spaced apart from the first pad in a first direction parallel to a first boundary of the chip mounting region; and
a branch line pattern extending between the main line pattern and the second pad and electrically connecting the first bump structure to the second bump structure,
wherein the first pad extends from one edge of the first bump structure to an opposite edge of the first bump structure in a second direction perpendicular to the first direction in a plan view,
wherein the second pad extends from one edge of the second bump structure to an opposite edge of the second bump structure in the second direction in the plan view, and
wherein the branch line pattern is spaced apart from a first side surface of the first pad most adjacent to the first boundary of the chip mounting region and a first side surface of the second pad most adjacent to the first boundary of the chip mounting region.

14. The COF package of claim 13, wherein, in a plan view, each of the first bump structure and the second bump structure has a rectangular shape of which length in the first direction is smaller than a length in the second direction.

15. The COF package of claim 13, wherein
the plurality of bump structures further include third bump structures arranged along a second boundary of the chip mounting region extending in the second direction, and
a length of the first boundary of the chip mounting region is smaller than a length of the second boundary of the chip mounting region.

16. The COF package of claim 15, wherein the film substrate further includes input/output interconnect patterns extending from one edge of the base film to the third bump structures.

17. The COF package of claim 13, wherein the branch line pattern is entirely within the chip mounting region.

18. The COF package of claim 13, wherein
the plurality of bump structures include one or more bump structures disposed between the first bump structure and the second bump structure in the first direction, and
the branch line pattern extends in a path through the outer region of the chip mounting region.

19. The COF package of claim 13, wherein the first bump structure and the second bump structure are configured to receive the same power signal through the branch line pattern.

20. A display apparatus comprising:
a chip on film (COF) package comprising a film substrate, a plurality of bump structures on the film substrate, and a display driving chip on the plurality of bump structures;
a display panel electrically connected to the film substrate; and
a driving printed circuit board electrically connected to the film substrate,
wherein the plurality of bump structures comprise a first bump structure and a second bump structure,
wherein the film substrate comprises:
a base film having a chip mounting region and an outer region surrounding the chip mounting region, wherein the chip mounting region vertically overlaps the display driving chip;
a main line pattern extending on the chip mounting region of the base film, the main line pattern comprising a first pad electrically coupled to the first bump structure and a first extension pattern electrically connected to the first pad;
a second pad electrically coupled to the second bump structure and spaced apart from the first pad in a first direction parallel to a first boundary of the chip mounting region; and
a branch line pattern extending between the main line pattern and the second pad and electrically connecting the first bump structure to the second bump structure,
wherein the first pad extends from one edge of the first bump structure to another edge of the first bump structure opposite the one edge of the first bump structure in a second direction perpendicular to the first direction in a plan view,
wherein the second pad extends from one edge of the second bump structure to an opposite edge of the second bump structure in the second direction in the plan view, and
wherein the branch line pattern is spaced apart from a first side surface of the first pad most adjacent to the first boundary of the chip mounting region and a first side surface of the second pad most adjacent to the first boundary of the chip mounting region.
